(19) United States
(12) Patent Application Publication
(10) Pub. No.: US 2019/0357346 A1
(43) Pub. Date: Nov. 21, 2019

(54) HEAT DISSIPATION SUBSTRATE, METHOD FOR PREPARING SAME, APPLICATION OF SAME, AND ELECTRONIC DEVICE

(71) Applicant: BYD COMPANY LIMITED, Shenzhen (CN)

(72) Inventors: Junlan LIAN, Shenzhen (CN); Hongye LIN, Shenzhen (CN)

(73) Assignee: BYD COMPANY LIMITED, Shenzhen (CN)

(21) Appl. No.: 16/474,643

(22) PCT Filed: Dec. 8, 2017
(86) PCT No.: PCT/CN2017/115153

§ 371 Date: Jun. 28, 2019

(30) Foreign Application Priority Data
Dec. 29, 2016 (CN) 201611249692.9

(51) Int. Cl. H05K 1/02; H01L 23/00

(52) U.S. Cl. CPC H05K 1/0209; H01L 24/03; H01L 23/367; H05K 1/0212; H01L 2224/48091; H05K 1/021

(57) ABSTRACT

The present disclosure A heat dissipation substrate includes: a metal-ceramic composite board, where the metal-ceramic composite board is a metal layer wrapping a ceramic body; a metal oxide layer integrated with the metal layer and formed on an outer surface of the metal layer; and a conductive layer formed on at least a part of an outer surface of the metal oxide layer, where a conductive trace is formed on the conductive layer, and is used to connect with and bear a chip.

### CROSS-REFERENCE TO RELATED APPLICATIONS

This application is the U.S. national phase entry of PCT Application No. PCT/CN2017/115153, filed on Dec. 8, 2017, which claims priority to and benefits of Chinese Patent Application No. 201611249692.9, filed with the State Intellectual Property Office of P. R. China on Dec. 29, 2016. The entire contents of the above-referenced applications are incorporated herein by reference.

### FIELD

The present disclosure relates to the field of heat dissipation substrates for encapsulating electronic devices, and specifically, to a heat dissipation substrate, a method for preparing same, an application of same, and an electronic device.

### BACKGROUND

In a process of preparing an electronic device, an encapsulating material usually needs to be used to resolve a thermal failure problem of an electronic circuit such as a chip. The encapsulating material not only needs to play a role of being capable of soldering a copper substrate and bearing a chip, but also needs to be responsible for heat dissipation at the same time. Because the encapsulating material is in contact with a cooling liquid in a process of performing heat exchange, the encapsulating material is further required to have anticorrosion performance.

Therefore, during actual use, the encapsulating material is usually applied in a substrate form, and it is required that a surface of the substrate is used for soldering the copper substrate and bearing the chip, and can have a soldering function; and another opposite surface is in contact with the cooling liquid to implement heat dissipation, and can have an anticorrosion function. To satisfy this requirement, a current usual solution is to perform nickel plating on the entire substrate. However, this imposes a strict requirement on quality of a surface of the substrate. If there are a pit, a sand hole, and the like, nickel plating cannot cover up these defects. As a result, a soldering yield rate is low. Although the thickness of a plating layer may be increased through design of a plating layer structure, production costs are increased evidently.

In the prior art, in the process of preparing an electronic device, a nickel plating method is taken to resolve the heat dissipation problem and the anticorrosion problem of the encapsulating material. However, there are defects that the product yield rate is low and costs are high.

### SUMMARY

An objective of the present disclosure is to resolve the foregoing problem existing in a heat dissipation substrate used for encapsulating an electronic device, so as to provide a heat dissipation substrate, a method for preparing same, an application of same, and an electronic device.

In order to achieve the foregoing objective, the present disclosure provides a heat dissipation substrate. The heat dissipation substrate includes: a metal-ceramic composite board, where the metal-ceramic composite board is a metal layer wrapping a ceramic body; a metal oxide layer integrated with the metal layer and formed on an outer surface of the metal layer; and a conductive layer formed on at least a part of an outer surface of the metal oxide layer, where a conductive trace is formed on the conductive layer, and is used to connect with a chip and bear a chip.

The present disclosure further provides a method for preparing a heat dissipation substrate of the present disclosure, including: directly performing metal oxidation on a metal-ceramic composite board, where the metal-ceramic composite board is a composite board material in which a metal layer wraps a ceramic body; forming a metal oxide layer integrated with the metal layer on an outer surface of the metal layer; and forming a conductive layer on at least a part of an outer surface of the metal oxide layer.

The present disclosure further provides an application of a heat dissipation substrate of the present disclosure in an electronic device.

The present disclosure further provides an electronic device. The electronic device includes: a heat dissipation substrate, where the heat dissipation substrate has a conductive layer; and a soldering layer and a chip sequentially stacked on at least a part of an outer surface of the conductive layer, where the chip is connected to the conductive layer through a conducting wire; and the heat dissipation substrate is a heat dissipation substrate of the present disclosure.

Through the foregoing technical solutions, direct oxidation is performed on the outer surface of the metal layer of the metal-ceramic composite board in situ to form the metal oxide layer, the heat dissipation substrate having heat dissipation, anticorrosion, and soldering functions may be provided, and the heat dissipation substrate has a larger bonding strength, and may better bear the chip, so as to overcome the defects of the nickel plating method taken in the prior art. Through the foregoing technical solutions, the obtained heat dissipation substrate may be provided with better anticorrosion performance when a neutral salt spray test is performed; the obtained heat dissipation substrate may be provided with a better bonding strength between the metal oxide layer and the metal layer of the metal-ceramic composite board when a bonding performance test is performed; and the obtained heat dissipation substrate may be provided with good wetting performance and good soldering performance when a sessile drop test is performed.

Based on the heat dissipation substrate, the conductive layer may be directly formed on the outer surface of the metal oxide layer, and has the conductive trace that may be directly used to connect with the chip when the electronic device is formed, to save a soldering metal layer, a lining board, a redundant soldering layer, and a copper substrate, thereby reducing the thickness of the electronic device.

Other features and advantages of the disclosure are described in detail in the subsequent specific implementations.

### BRIEF DESCRIPTION OF THE DRAWINGS

The accompanying drawing is used to further understand the disclosure and constitute a part of the specification, and is used to explain the disclosure together with the following specific implementations, but does not constitute a limitation on the disclosure. In the accompanying drawings:

FIG. 1 is a schematic structural diagram of a heat dissipation substrate;

FIG. 2 is a schematic structural diagram of an electronic device; and

FIG. 3 is a schematic diagram of a contact angle θ in a sessile drop test.

Description of the reference signs:

| | | | | | |
|---|---|---|---|---|---|
| 1 | metal-ceramic | 2 | metal oxide layer | 3 | conductive layer |
| | composite board | | | | |
| 4 | soldering layer | 5 | conducting wire | 6 | chip |

### DETAILED DESCRIPTION

Specific implementations of the disclosure are described in detail below. It should be understood that the specific implementations described herein are merely used to describe and explain the present disclosure rather than limit the present disclosure.

Endpoints of all ranges and all values disclosed herein are not limited to the precise ranges or values, and these ranges or values should be understood as including values close to these ranges or values. For value ranges, endpoint values of the ranges, an endpoint value of each range and an independent point value, and independent point values may be combined with each other to obtain one or more new value ranges, and these value ranges should be considered as being specifically disclosed herein.

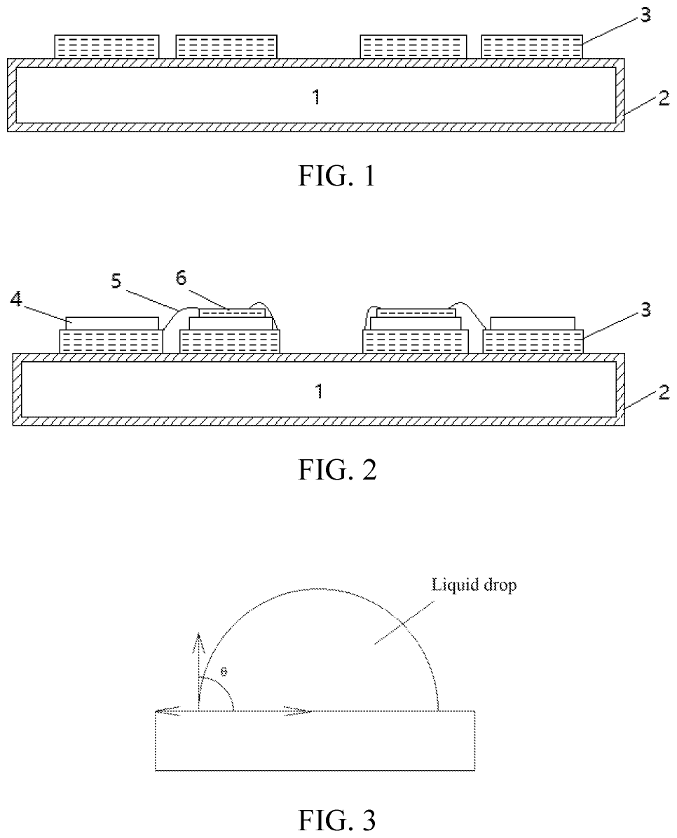

The present disclosure is to provide a heat dissipation substrate, as shown in FIG. 1. The heat dissipation substrate includes: a metal-ceramic composite board 1, where the metal-ceramic composite board is a metal layer wrapping a ceramic body; a metal oxide layer 2 integrated with the metal layer and formed on an outer surface of the metal layer; and a conductive layer 3 formed on at least a part of an outer surface of the metal oxide layer, where a conductive trace is formed on the conductive layer 3, and is used to connect with and bear a chip.

According to the present disclosure, the metal oxide layer is formed by directly oxidizing the metal layer, to wrap the metal layer. The metal oxide layer is formed by directly oxidizing the metal layer in situ, and may have a larger bonding strength. Photographing and observation may be performed through a metallographic microscope, and it is observed on a section of the heat dissipation substrate provided in the present disclosure that there is no boundary between the metal layer of the metal-ceramic composite board and the metal oxide layer. However, if a metal oxide layer is obtained by coating or depositing a metal layer and then oxidizing the metal layer, it is observed through the metallographic microscope that an evident boundary exists between the metal layer of the metal-ceramic composite board and the formed metal oxide layer. Further, the metal oxide layer may be provided with a soldering surface (or surface A) and a heat dissipation surface (or surface B). The soldering surface (or surface A) and the heat dissipation surface (or surface B) may be two opposite surfaces on the heat dissipation substrate, and are usually two surfaces on the heat dissipation substrate that have maximum areas. The conductive layer is disposed on only the soldering surface and may be further used to solder the chip. The heat dissipation surface may be in contact with a cooling liquid and is used for heat dissipation. In some embodiments, the conductive layer is disposed on the metal oxide layer on a side of the heat dissipation substrate; and the metal oxide layer on another side opposite to the side is used to be in contact with the cooling liquid, to perform heat dissipation.

In the present disclosure, in some embodiments, the conductive layer is used to form the conductive trace, and may be further connected to the subsequently soldered chip.

By forming the metal oxide layer through oxidation performed in situ, the heat dissipation substrate provided in the present disclosure may have better bonding strength, soldering performance, and anticorrosion performance, and then the conductive layer may be directly formed. When the chip is further encapsulated to form the electronic device, regular components such as a soldering metal layer and a lining board are removed from the structure of the electronic device, to reduce the thickness of the electronic device.

According to the present disclosure, for the heat dissipation substrate, a substrate material regularly used in an encapsulating material of an electronic device, for example, a base material containing metal may be selected as a base material, and the metal-ceramic composite board may be selected as a base material. Then, the metal oxide layer and the conductive layer are formed on this base material. In some embodiments, the ceramic body is selected from a SiC ceramic body or a Si ceramic body; and the metal layer is an Al metal layer, an Mg metal layer, or a Ti metal layer. The metal-ceramic composite board may be commercially available. The thickness of the ceramic body may be not particularly limited, and may be approximately 3 mm.

According to the present disclosure, the metal oxide layer is formed by the metal layer in situ, and the metal oxide layer is an oxide corresponding to metal used for the metal layer. The metal oxide layer is an aluminum oxide layer, a magnesium oxide layer, or a titanium oxide layer.

According to the present disclosure, a regular conductive material may be selected to form the conductive layer. In some embodiments, the conductive layer is a copper metal layer or a silver metal layer.

According to the present disclosure, it is only required that the thickness of each layer included in the heat dissipation substrate can implement the heat dissipation function, the anticorrosion function, and the function of bearing the chip. In some embodiments, the thickness of the metal layer is 20 μm to 500 μm; the thickness of the metal oxide layer is 5 μm to 300 μm; and the thickness of the conductive layer is 3 μm to 400 μm.

According to the present disclosure, the metal layer and the metal oxide layer in the heat dissipation substrate may have better bonding strength between each other. In some embodiments, a bonding strength between the metal oxide layer and the metal layer is above 20 MPa. For example, the bonding strength reaches 20 MPa to 30 MPa. The bonding strength may be tested through GB/T 8642-2002.

In an implementation of the present disclosure, the conductive layer is disposed on a side of the heat dissipation substrate. In some embodiments, the thickness of the metal oxide layer on the side of the heat dissipation substrate on which the conductive layer is disposed is greater than or equal to the thickness of the metal oxide layer on another side opposite to the side. That is, the thickness of the metal oxide layer on the soldering surface (as described above, a side of the heat dissipation substrate on which the conductive layer is formed) needs to be greater than or equal to the thickness of the metal oxide layer on the heat dissipation surface (as described above, another side opposite to the side of the heat dissipation substrate on which the conductive layer is formed). For example, the thickness of the metal oxide layer on the soldering surface may be 80 μm to 300 μm, and the thickness of the metal oxide layer on the heat dissipation surface is 40 μm to 100 μm.

A second objective of the present disclosure is to provide a method for preparing a heat dissipation substrate of the present disclosure, including: directly performing metal oxidation on a metal-ceramic composite board, and forming a metal oxide layer integrated with a metal layer[SY1] on an outer surface of the metal layer; and forming a conductive layer on at least a part of an outer surface of the metal oxide layer, where the metal-ceramic composite board is a composite board material in which the metal layer wraps a ceramic body.

According to the present disclosure, a conventional material applicable to encapsulation of an electronic device may be selected, and may be a material containing metal. For example, the metal-ceramic composite board may be used as a base material for forming the heat dissipation substrate. The ceramic body may be selected from a SiC ceramic body or a Si ceramic body; and the metal layer may be selected from an Al metal layer, an Mg metal layer, or a Ti metal layer. The thickness of the ceramic body may be not particularly limited, and may be approximately 3 mm. The thickness of the metal layer may be 20 μm to 500 μm. Further, the metal oxide layer may be directly formed in situ on the outer surface of the metal layer in the metal-ceramic composite board through the metal oxidation. If the metal layer is an Al metal layer, an aluminum oxide layer is obtained. If the metal layer is an Mg metal layer, a magnesium oxide layer is obtained. If the metal layer is a Ti metal layer, a titanium oxide layer is obtained.

In the present disclosure, two surfaces on the heat dissipation substrate that have large areas may be used as the soldering surface and the heat dissipation surface. In an implementation, the thickness of the metal oxide layer on the soldering surface is greater than or equal to the thickness of the metal oxide layer on the heat dissipation surface. The soldering surface may be used to further dispose the conductive layer, a soldering layer, and a chip sequentially stacked. The heat dissipation surface is in contact with a cooling liquid to play a role of heat dissipation. In some embodiments, a method for forming metal oxide layers having different thicknesses on the soldering surface and the heat dissipation surface may be: single-sided cathodic oxidation, masking oxidation, or secondary oxidation.

In the present disclosure, a method for single-sided cathodic oxidation may be: the metal oxide layer of the soldering surface faces to a cathode, and no cathode is disposed on the heat dissipation surface. A method for masking oxidation may be: a baffle is disposed to make oxidation thicknesses of two surfaces, namely, the soldering surface and the heat dissipation surface different. For example, a method for secondary oxidation may be: a fixture is used for shading on the heat dissipation surface to prevent the heat dissipation surface from being in contact with a medicinal liquid, the fixture is removed when a particular thickness (approximately 40 μm) is obtained through oxidation, the two surfaces are evenly oxidized, and the thicknesses of the metal oxide layers on the soldering surface and the heat dissipation surface may have a difference of approximately 40 μm.

In the present disclosure, the metal oxidation may include a plurality of specific implementation methods, as long as a metal oxide layer satisfying a required thickness is formed on the outer surface of the metal layer in the metal-ceramic composite board. In some embodiments, a method for the metal oxidation may include anodic oxidation or micro-arc oxidation. Specifically, a method and a condition for anodic oxidation include: removing surface oil contamination and a surface oxide layer from the metal-ceramic composite board, then placing the metal-ceramic composite board in a chemical oxidation solution, and electrifying the chemical oxidation solution for 10 min to 30 min to perform sealing treatment. The sealing treatment may be performed by using hot water. The oxidation solution is a solution containing 180 g/L to 220 g/L of sulfuric acid, the temperature is −5° C. to 25° C., the voltage is 10 V to 22 V, and the current density is 0.5 A/dm² to 2.5 A/dm².

A method and a condition for micro-arc oxidation include: removing surface oil contamination from the metal-ceramic composite board, then placing the metal-ceramic composite board in a micro-arc oxidation solution in a micro-arc oxidation tank, electrifying the micro-arc oxidation solution to perform micro-arc oxidation, and performing hot water sealing after micro-arc oxidation is completed. The micro-arc oxidation solution is usually a weakly basic solution, and may contain a silicate, a phosphate, a borate, or the like. The temperature of micro-arc oxidation is controlled to be 20° C. to 60° C., and the voltage may be usually controlled to be 400 V to 750 V. The micro-arc oxidation may alternatively be implemented by using a low-voltage micro-arc oxidation technology.

In an implementation of the present disclosure, the thickness of the formed metal oxide layer may be 5 μm to 300 μm. Further, the thickness of the metal oxide layer on the soldering surface may be 80 μm to 300 μm, and the thickness of the metal oxide layer on the heat dissipation surface is 40 μm to 100 μm.

According to the present disclosure, the conductive layer is used to form a conductive trace, and may be used to further connect with the chip. In some embodiments, a method for forming the conductive layer includes: performing surface masking on the metal oxide layer, then spraying conductive metal to obtain a conductive trace, and forming the conductive layer; or spraying or sputtering conductive metal on the metal oxide layer, then performing mask etching to obtain a conductive trace, and forming the conductive layer. The conductive metal may be selected from copper or silver, is of a powder shape, and has an average particle diameter of 1 μm to 50 μm. The conductive metal may be a known substance such as copper powder of 37 μm of a model TITD-Q Cu commercially available from Tianjiu Metal Material Co., Ltd. It is only required that the spraying is implemented to obtain the conductive trace having a sufficient thickness and requirement to form the conductive layer. In some embodiments, the thickness of the conductive layer that may be formed through the method for forming the conductive layer is 3 μm to 400 μm.

In the present disclosure, spraying used for forming the conductive layer may be cold spraying, including: removing oil contamination from a surface of the formed metal oxide layer, then performing borax treatment, and then entering a cold spraying procedure, where gas is nitrogen gas and/or helium gas; the cold spraying pressure is 1.5 MPa to 3.5 MPa; the spraying distance is 10 mm to 50 mm; and the particle feed rate is 3 kg/h to 15 kg/h. The particle feed rate is a rate of spraying the conductive metal when the cold spraying is performed.

In the present disclosure, when the spraying is performed, a part on the metal oxide layer that does not need to be sprayed may be protected by using a masking method.

In the present disclosure, the foregoing preparation method may further include: first pre-treating the metal-ceramic composite board, degreasing and dewaxing the metal-ceramic composite board, further removing the oxide layer formed on the outer surface of the metal layer of the metal-ceramic composite board due to natural oxidation, and then performing the metal oxidation in the foregoing preparation method provided in the present disclosure. For example, degreasing and dewaxing may be performed by immersing the metal-ceramic composite board in an ethyl alcohol solution for 5 min, or immersing the metal-ceramic composite board in degreasing powder U-151 (Atotech) for 5 min at 50° C. A method and a condition for removing the oxide layer formed due to natural oxidation may be: immersing the metal-ceramic composite board for 3 min in an aqueous sodium hydroxide solution whose concentration is 50 g/L, or immersing the metal-ceramic composite board for 1 min at a room temperature in a tank liquid configured by hot-dipping electrolytic deterging powder U-152.

In the present disclosure, the foregoing preparation method may further include: after the metal oxidation step is completed, sealing and drying the obtained board material, and then performing the metal spraying. The function of sealing may be to seal holes formed during oxidation. Sealing may be implemented by using a boiling water sealing method. Drying may be performed for 20 min to 30 min at 80° C. to 100° C.

A third objective of the present disclosure is to provide an application of a heat dissipation substrate of the present disclosure in an electronic device. The heat dissipation substrate of the present disclosure may be used as an encapsulating material in an electronic device.

A fourth objective of the present disclosure is to provide an electronic device, as shown in FIG. 2. The electronic device includes: a heat dissipation substrate 1, where the heat dissipation substrate has a conductive layer 3; and a soldering layer 4 and a chip 6 sequentially stacked on at least a part of an outer surface of the conductive layer, where the chip is connected to the conductive layer through a conducting wire 5; and the heat dissipation substrate is a heat dissipation substrate of the present disclosure. The heat dissipation substrate includes: a metal-ceramic composite board in which a metal layer wraps a ceramic body; a metal oxide layer integrated with the metal layer and formed on an outer surface of the metal layer; and the conductive layer formed on at least a part of an outer surface of the metal oxide layer.

In the electronic device of the present disclosure, the heat dissipation substrate provides functions of bearing the chip and dissipating heat of the chip. A side of the heat dissipation substrate on which the conductive layer is formed is further provided with the soldering layer and the chip, to bear the chip; and another opposite side does not have the conductive layer, may be in contact with a cooling liquid, and is used as a cooling surface to dissipate heat of the chip. Because the cooling liquid is corrosive, and the cooling surface of the heat dissipation substrate has the metal oxide layer formed in situ by directly oxidizing the metal layer, an anticorrosion function may be provided.

In the electronic device of the present disclosure, the soldering layer is used to connect the conductive layer to the chip. The soldering layer may be formed through a tin soldering method by using a tin paste.

In the electronic device of the present disclosure, the conducting wire connects the chip to the conductive layer, or a regular method in the art may be used. Details are not described herein again.

The disclosure is described in detail below by using embodiments.

In the following embodiments and comparison examples, a metal-ceramic composite board is an Al—SiC composite board from HWT Technology Co., Ltd.

Soldering performance passes through a sessile drop technique (Sessile Drop) test: A melted solder liquid is dripped onto a surface of a conductive layer of a clean and smooth heat dissipation substrate, and after a balanced and stable state is reached, photographing is performed as shown in FIG. 3. A photograph is enlarged, a contact angle θ is directly measured, and a corresponding liquid-solid interfacial tension is calculated through the angle θ. The contact angle θ in the method may be used to represent whether wetting is qualified: if θ<90°, it is referred to as wetting; if θ>90°, it is referred to as non-wetting; if θ=0°, it is referred to as complete wetting; and if θ=180°, it is referred to as complete non-wetting. Wetting represents good soldering performance, and is indicated by using “OK”; and non-wetting represents poor soldering performance.

Anticorrosion performance of the heat dissipation substrate passes through a neutral salt spray test: The heat dissipation substrate is inclined by 15° to 30°, so that a to-be-tested surface can accept salt spray at the same time; conditions are (5±0.1)% NaCl solution; the pH value is between 6.5 to 7.2; the salt spray settling amount is 1 to 2 ml/80 cm²·h; and the temperature is 35±2° C. The surface of the tested sample is observed, and time points at which bubbling and rusting occur are recorded.

The bonding strength between a metal oxide layer and a metal-ceramic composite board of a heat dissipation substrate in the embodiments, and the bonding strength between a nickel layer and a metal-ceramic composite board of a heat dissipation substrate in the comparison examples are tested according to GB/T 8642-2002.

### Embodiment 1

This embodiment describes a heat dissipation substrate of the present disclosure and a method for preparing same.

An Al—SiC composite board (the thickness of SiC is 3 mm, and the thickness of Al is 100 μm) is immersed for 5 min in degreasing powder U-151 (Atotech) at 50° C. to perform degreasing and dewaxing, and then immersed for 1 min at a room temperature in a tank liquid configured by hot-dipping electrolytic deterging powder U-152 to perform deoxidation[SY2], to obtain a to-be-oxidized substrate.

A side of the to-be-oxidized substrate is used as a heat dissipation surface and shaded by using a fixture, then the heat dissipation surface is placed in an oxidation solution containing 180 g/L of sulfuric acid (98 wt %), the first time of anodic oxidation is performed for 50 min at −5° C., 10 V, and 1 A/cm³, and an aluminum oxide layer whose thickness is 40 μm is obtained on a side that is not shaded to serve as a soldering surface; the fixture is removed, then the heat dissipation surface is placed in the foregoing oxidation solution, the second time of anodic oxidation is performed under the same condition, then sealing is performed for 5 min at 95° C. by using purified water, and then drying is performed for 30 min at 80° C.; a to-be-sprayed substrate is obtained; and the thickness of the aluminum oxide layer of the heat dissipation surface is 40 μm, and the thickness of the aluminum oxide layer of the soldering surface is 80 μm.

A jig on which a conductive trace pattern is drawn is used to mask a part of the soldering surface of the to-be-sprayed substrate, and then cold spraying of copper is performed: nitrogen gas, the pressure is 2.5 MPa, the spraying distance is 30 mm, the copper powder feed (TITD-Q Cu) rate is 10 kg/h, and a conductive layer whose thickness is 10 μm is obtained; and a heat dissipation substrate is obtained.

Tests of soldering performance, anticorrosion performance, and bonding performance are performed on the heat dissipation substrate, and results are seen in Table 2.

### Embodiment 2

This embodiment describes a heat dissipation substrate of the present disclosure and a method for preparing same.

An Al—SiC composite board (the thickness of SiC is 3 mm, and the thickness of Al is 300 μm) is immersed in ethyl alcohol for 5 min to perform degreasing and dewaxing, and then immersed in 50 g/L of aqueous sodium hydroxide solution for 3 min, to obtain a to-be-oxidized substrate.

A side of the to-be-oxidized substrate is used as a heat dissipation surface and shaded by using a fixture, then the heat dissipation surface is placed in an oxidation solution containing 180 g/L of sulfuric acid (98 wt %), the first time of anodic oxidation is performed for 80 min at −5° C., 22 V, and 1 A/cm³, and an aluminum oxide layer whose thickness is 100 μm is obtained on a side that is not shaded to serve as a soldering surface; the fixture is removed, then the heat dissipation surface is placed in the foregoing oxidation solution, the second time of anodic oxidation is performed under the same condition, then sealing is performed for 5 min at 95° C. by using purified water, and then drying is performed for 30 min at 80° C.; a to-be-sprayed substrate is obtained; and the thickness of the aluminum oxide layer of the heat dissipation surface is 100 μm, and the thickness of the aluminum oxide layer of the soldering surface is 200 μm.

A jig on which a conductive trace pattern is drawn is used to mask a part of the soldering surface of the to-be-sprayed substrate, and then cold spraying of copper is performed: nitrogen gas, the pressure is 3 MPa, the spraying distance is 40 mm, the copper powder feed rate is 10 kg/h, and a conductive layer whose thickness is 400 μm is obtained; and a heat dissipation substrate is obtained.

Tests of soldering performance, anticorrosion performance, and bonding performance are performed on the heat dissipation substrate, and results are seen in Table 2.

### Embodiment 3

This embodiment describes a heat dissipation substrate of the present disclosure and a method for preparing same.

An Al—SiC composite board (the thickness of SiC is 3 mm, and the thickness of Al is 500 μm) is immersed for 5 min in degreasing powder U-151 (Atotech) at 50° C. to perform degreasing and dewaxing, and then immersed for 1 min at a room temperature in a tank liquid configured by hot-dipping electrolytic deterging powder U-152 to perform deoxidation, to obtain a to-be-oxidized substrate.

A side of the to-be-oxidized substrate is used as a heat dissipation surface and shaded by using a fixture, then the heat dissipation surface is placed in an oxidation solution containing 180 g/L of sulfuric acid (98 wt %), the first time of anodic oxidation is performed for 90 min at −5° C., 22 V, and 1 A/cm³, and an aluminum oxide layer whose thickness is 70 μm is obtained on a side that is not shaded to serve as a soldering surface; the fixture is removed, then the heat dissipation surface is placed in the foregoing oxidation solution, the second time of anodic oxidation is performed under the same condition, then sealing is performed for 5 min at 95° C. by using purified water, and then drying is performed for 30 min at 80° C.; a to-be-sprayed substrate is obtained; and the thickness of the aluminum oxide layer of the heat dissipation surface is 70 and the thickness of the aluminum oxide layer of the soldering surface is 140 μm.

A jig on which a conductive trace pattern is drawn is used to mask a part of the soldering surface of the to-be-sprayed substrate, and then cold spraying of copper is performed: helium gas, the pressure is 2 MPa, the spraying distance is 30 mm, the copper powder feed rate is 10 kg/h, and a conductive layer whose thickness is 300 μm is obtained; and a heat dissipation substrate is obtained.

Tests of soldering performance, anticorrosion performance, and bonding performance are performed on the heat dissipation substrate, and results are seen in Table 2.

### Embodiment 4

On the heat dissipation substrate of Embodiment 1, a soldering layer is formed on a conductive layer through a tin soldering method by using a tin paste; and then a chip is connected on the soldering layer, the chip is connected to the conductive layer through a leading wire, to obtain an electronic device whose structure is shown in FIG. 2, and the total thickness of the electronic device is 4.3 mm.

### COMPARISON EXAMPLE 1

An Al—SiC composite board (the thickness of SiC is 3 mm, and the thickness of Al is 100 μm) is immersed in ERPREP Flex (Atotech) for 5 min at 50° C. to perform degreasing and dewaxing, and then immersed for 3 min in a tank liquid configured by Actane 4322s to perform deoxidation; and a treated substrate is obtained.

Nickel plating is performed on the treated substrate according to a process shown in Table 1, to obtain a nickel layer whose thickness is 10 μm; and a heat dissipation substrate is obtained. Chemicals are products commercially available from Cookson-Enthone Chemistry.

TABLE 1

| Procedure | Chemical | Temperature | Time | |
|---|---|---|---|---|
| Deterging | ENPLATE BS | Room | 3 | min |
| | | temperature | | |
| Water washing | Purified water | Room | 1 | min |
| | | temperature | | |
| Zinc galvanizing 1 | ENPLATE BS EN | Room | 1 | min |
| | | temperature | | |
| Water washing | Purified water | Room | 1 | min |
| | | temperature | | |
| Zinc stripping | 50% nitric acid | Room | 1 | min |
| | | temperature | | |
| Water washing | Purified water | Room | 1 | min |
| | | temperature | | |
| Zinc galvanizing 1 | ENPLATE BS EN | Room | 30 | s |
| | | temperature | | |
| Water washing | Purified water | Room | 1 | min |
| | | temperature | | |
| Basic nickel | ENPLATE ENI-120 | Room | 10 | min |
| | | temperature | | |
| Water washing | Purified water | Room | 1 | min |
| | | temperature | | |
| Nickel plating | ENPLATE ENI-807 | 85° C. | 60 | min |
| Water washing | Purified water | Room | 1 | min |
| | | temperature | | |
| Drying | | 80° C. | 30 | min |

Tests of soldering performance, anticorrosion performance, and bonding performance are performed on the heat dissipation substrate, and results are seen in Table 2.

### COMPARISON EXAMPLE 2

According to the method of Embodiment 4, the heat dissipation substrate prepared in the comparison example 1 is used to encapsulate a chip, and a first soldering layer, a first copper substrate, a lining board, a second copper substrate, a second soldering layer, and the chip are sequentially stacked on a nickel layer, to prepare an electronic device. The total thickness of the electronic device is 5.13 mm.

TABLE 2

| | Soldering | Anticorrosion | Bonding |
|---|---|---|---|
| Number | performance | performance | performance |
| Embodiment 1 | OK | 1000 h | 20 MPa |
| Embodiment 2 | OK | 1000 h | 30 MPa |
| Embodiment 3 | OK | 1000 h | 25 MPa |
| Comparison example 1 | OK | 24 h | 10 MPa |

It may be seen from the embodiments, the comparison example, and data results in Table 2 that, the heat dissipation substrate provided in the present disclosure may have good anticorrosion performance, bonding performance, and soldering performance at the same time. Moreover, the heat dissipation substrate provided in the present disclosure has a simpler technology, is industrialized conveniently, and is reduced in use of nickel, costs and discharging of nickel liquid waste are reduced, and the present disclosure provides the heat dissipation substrate with better performance in a more environmentally-friendly manner. However, the heat dissipation substrate obtained in the comparison examples may satisfy soldering performance, but anticorrosion performance and bonding performance are both quite poor.

Moreover, it may be seen by comparing Embodiment 4 with the comparison example 2 that, the heat dissipation substrate provided in the present disclosure may be prepared to reduce the thickness of the electronic device.

What is claimed is:

1. A heat dissipation substrate, comprising:
a metal-ceramic composite board, wherein the metal-ceramic composite board is a metal layer wrapping a ceramic body;
a metal oxide layer integrated with the metal layer and formed on an outer surface of the metal layer; and
a conductive layer formed on at least a part of an outer surface of the metal oxide layer, wherein a conductive trace is formed on the conductive layer, and is configured to connect with a chip and bear a chip.

2. The heat dissipation substrate according to claim 1, wherein the metal oxide layer is formed by directly oxidizing the metal layer.

3. The heat dissipation substrate according to claim 1, wherein the ceramic body is a SiC ceramic body or a Si ceramic body; the metal layer is an Al metal layer, an Mg metal layer, or a Ti metal layer; the metal oxide layer is an aluminum oxide layer, a magnesium oxide layer, or a titanium oxide layer; and the conductive layer is a copper metal layer or a silver metal layer.

4. The heat dissipation substrate according to claim 3, wherein a thickness of the metal layer is about 20 μm to about 500 μm; a thickness of the metal oxide layer is about 5 μm to about 300 μm; and the a thickness of the conductive layer is about 3 μm to about 400 μm.

5. The heat dissipation substrate according to claim 1, wherein a bonding strength between the metal oxide layer and the metal layer is above 20 MPa.

6. The heat dissipation substrate according to claim 1, wherein the conductive layer is disposed on a side of the heat dissipation substrate.

7. The heat dissipation substrate according to claim 6, wherein the thickness of the metal oxide layer on the side of the heat dissipation substrate on which the conductive layer is disposed is greater than or equal to the thickness of the metal oxide layer on another side opposite to the side.

8. A method for preparing the heat dissipation substrate according to claim 1, comprising:
directly performing metal oxidation on a metal-ceramic composite board, wherein the metal-ceramic composite board is a composite board material in which a metal layer wraps a ceramic body;
forming a metal oxide layer integrated with the metal layer on an outer surface of the metal layer; and
forming a conductive layer on at least a part of an outer surface of the metal oxide layer.

9. The method according to claim 8, wherein the metal oxidation comprises anodic oxidation or micro-arc oxidation.

10. The method for preparing the heat dissipation substrate according to claim 8, wherein the step of forming the conductive layer comprises:
performing surface masking on the metal oxide layer, then spraying conductive metal to obtain a conductive trace, and forming the conductive layer; or
spraying or sputtering conductive metal on the metal oxide layer, then performing mask etching to obtain a conductive trace, and forming the conductive layer.

11. The method for preparing the heat dissipation substrate according to claim 8, wherein the thickness of the formed metal oxide layer is about 5 μm to about 300 μm; and the thickness of the formed conductive layer is about 3 μm to about 400 μm.

12. An application of the heat dissipation substrate according to claim 1 in an electronic device.

13. An electronic device, comprising:
a heat dissipation substrate, having a conductive layer; and
a soldering layer and a chip sequentially stacked on at least a part of an outer surface of the conductive layer, wherein the chip is connected to the conductive layer through a conducting wire; and
the heat dissipation substrate is the heat dissipation substrate according to claim 1.

14. The heat dissipation substrate according to claim 2, wherein the ceramic body is a SiC ceramic body or a Si ceramic body; the metal layer is an Al metal layer, an Mg metal layer, or a Ti metal layer; the metal oxide layer is an aluminum oxide layer, a magnesium oxide layer, or a titanium oxide layer; and the conductive layer is a copper metal layer or a silver metal layer.

15. The heat dissipation substrate according to claim 2, wherein a bonding strength between the metal oxide layer and the metal layer is above 20 MPa.

16. The heat dissipation substrate according to claim 15, wherein the conductive layer is disposed on a side of the heat dissipation substrate.

17. A method for preparing the heat dissipation substrate according to claim 16, comprising:
directly performing metal oxidation on a metal-ceramic composite board, wherein the metal-ceramic composite board is a composite board material in which a metal layer wraps a ceramic body;
forming a metal oxide layer integrated with the metal layer on an outer surface of the metal layer; and
forming a conductive layer on at least a part of an outer surface of the metal oxide layer.

18. The method according to claim 17, wherein the metal oxidation comprises anodic oxidation or micro-arc oxidation.

19. The method according to claim 18, wherein the step of forming the conductive layer comprises:
performing surface masking on the metal oxide layer, then spraying conductive metal to obtain a conductive trace, and forming the conductive layer; or
spraying or sputtering conductive metal on the metal oxide layer, then performing mask etching to obtain a conductive trace, and forming the conductive layer.

20. The method according to claim 18, wherein the thickness of the formed metal oxide layer is about 5 μm to about 300 μm; and the thickness of the formed conductive layer is about 3 μm to about 400 μm.
